(19) United States
(12) Patent Application Publication
(10) Pub. No.: US 2025/0308618 A1
(43) Pub. Date: Oct. 2, 2025

(54) CONCURRENT MAINTENANCE AND WRITE OPERATIONS

(71) Applicant: Micron Technology, Inc., Boise, ID (US)

(72) Inventors: Jameer Mulani, Bangalore (IN); Rakeshkumar Dayabhai Vaghasiya, Hyderabad (IN); Amiya Banerjee, Bangalore (IN); Nitul Gohain, Bangalore (IN)

(21) Appl. No.: 19/085,934

(22) Filed: Mar. 20, 2025

Related U.S. Application Data
(60) Provisional application No. 63/571,252, filed on Mar. 28, 2024.

(51) Int. Cl. G11C 29/52; G11C 16/08; G11C 16/10

(52) U.S. Cl. CPC G11C 29/52; G11C 16/08; G11C 16/102

(57) ABSTRACT

Methods, systems, and devices for concurrent maintenance and write operations are described. In some instances, a memory system may be performing a maintenance operation (e.g., a folding operation) and a write command may be received (e.g., from a host system). The memory system may suspend the maintenance operation and may write data associated with the write command using a first type of write operation (e.g., a single-pass write operation). After writing the data, the memory system may resume the maintenance operation. If an error control operation had been previously performed on data associated with the suspended (and subsequently resumed) maintenance operation, the associated data may be written using a second type of write operation (e.g., a two-pass write operation).

### CROSS REFERENCE

The present application for patent claims priority to U.S. Patent Application No. 63/571,252 by Mulani et al., entitled “CONCURRENT MAINTENANCE AND WRITE OPERATIONS,” filed Mar. 28, 2024, which is assigned to the assignee hereof, and which is expressly incorporated by reference in its entirety herein.

### TECHNICAL FIELD

The following relates to one or more systems for memory, including concurrent maintenance and write operations.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states if disconnected from an external power source.

### BRIEF DESCRIPTION OF THE DRAWINGS

FIGS. 1 and 2 each show an example of a system that supports concurrent maintenance and write operations in accordance with examples as disclosed herein.

FIG. 3 shows an example of a process that supports concurrent maintenance and write operations in accordance with examples as disclosed herein.

FIG. 4 shows a block diagram of a memory system that supports concurrent maintenance and write operations in accordance with examples as disclosed herein.

FIG. 5 shows a flowchart illustrating a method or methods that support concurrent maintenance and write operations in accordance with examples as disclosed herein.

### DETAILED DESCRIPTION

A memory system may support storing information in memory devices including memory cells capable of storing various quantities of bits of information. The memory system may include relatively higher storage density memory cells (e.g., which may be referred to as multi-programming pass cells), such as quad-level cells (QLCs), and may include relatively lower storage density memory cells (e.g., which may be referred to as single programming pass cells), such as single-level cells (SLCs), multi-level cells (MLCs), and triple-level cells (TLCs). Writing data to multi-programming pass cells may be associated with relatively high programming times, for example, due to involving multiple operations (e.g., stages, passes) to write the data. As a result, writing data to single programming pass cells (e.g., SLCs, MLCs, TLCs) may be faster than writing data to multi-programming pass cells (e.g., QLCs). As such, the memory system may initially write data (e.g., host data) to single programming pass cells, for example, to support faster host write performance (e.g., relative to initially storing the host data to QLCs) and then fold (e.g., transfer) the data to multi-programming pass cells, for example, to increase storage density and efficiency.

Some host systems may have write performance constraints, such as a quantity of data written per unit of time. To support satisfying the write performance constraints, the memory system may be configured to maintain an available die (or multiple dies) for host writes (e.g., write commands received from a host system). That is, the memory system may maintain at least one die available for host writes, and at least one die available for maintenance operations, such as folding operations. However, maintaining at least one die for maintenance operations may adversely affect the performance of host writes (e.g., the write performance may fall below or otherwise not satisfy the performance constraints). Accordingly, a memory system configured to perform maintenance operations while maintaining a relatively high host write performance may be desirable.

A memory system configured to perform maintenance operations while maintaining a relatively high host write performance is described herein. In some instances, a memory system may be performing a maintenance operation (e.g., a folding operation) and a write command may be received (e.g., from a host system). The memory system may suspend the maintenance operation and may write data associated with the write command using a first type of programming operation (e.g., a TLC programming operation, a single-pass programming operation). After writing the data, the memory system may resume the maintenance operation. If an error control operation had not been previously performed on data associated with the suspended (and subsequently resumed) maintenance operation, the memory system may resume the maintenance operation without sending the data out to a controller to perform an error control operation on the associated data, which may improve the overall performance of the memory system.

In addition to applicability in memory systems as described herein, techniques for concurrent maintenance and write operations may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds, which may decrease processing or latency times, improve response times, or otherwise improve user experience, among other benefits.

Features of the disclosure are illustrated and described in the context of systems, devices, and circuits. Features of the disclosure are further illustrated and described in the context of processes and flowcharts.

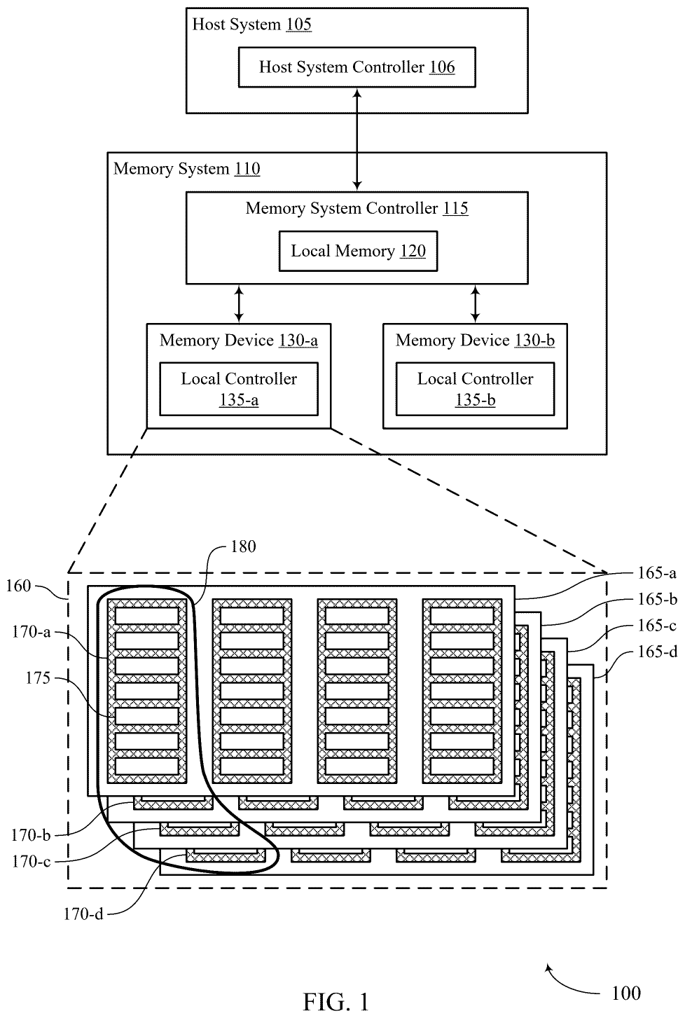

FIG. 1 shows an example of a system 100 that supports concurrent maintenance and write operations in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, L2P mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

The memory system 110 may include multi-programming pass cells (e.g., QLCs) and single programming pass cells (e.g., SLCs, MLCs, TLCs). That is, the memory system 110 (e.g., the memory system controller 115) may perform multiple operations (e.g., passes, stages of a programming operation) to write data to multi-programming pass cells, whereas, to write data to single programming pass cells, the memory system 110 may perform a single operation (e.g., a single pass). As such, writing to SLCs, MLCs, and TLCs, may be faster than writing to QLCs. Accordingly, in some examples, the memory system 110 may initially write data (e.g., host data) to single programming pass cells, for example, to support faster host write performance (e.g., relative to initially writing the host data to QLCs) and then fold (e.g., transfer) the data to multi-programming pass cells, for example, to increase the storage density and efficiency.

Some host systems 105 may have write performance constraints, such as a quantity of data written per unit of time (e.g., at least 60 megabytes (MB) per second (MB/s)). To support satisfying the write performance constraints, the memory system 110 may be configured to maintain an available die 160 (or multiple dies 160) for host writes. That is, the memory system 110 may maintain at least one die 160 available for host writes, and at least one die 160 available for maintenance operations. However, maintaining at least one die 160 for maintenance operations may adversely affect the performance of host writes (e.g., the write performance may fall below or otherwise not satisfy the performance constraints). Accordingly, a memory system (e.g., the memory system 110) configured to perform maintenance operations while maintaining a relatively high host write performance may be desirable.

In accordance with examples as disclosed herein, the memory system 110 may be configured to perform maintenance operations while maintaining a relatively high host write performance. In some instances, the memory system 110 may be performing a maintenance operation (e.g., a folding operation) and a write command may be received (e.g., from the host system 105). The memory system 110 may suspend the maintenance operation and may write data associated with the write command using a first type of programming operation (e.g., a TLC programming operation, a single-pass programming operation). After writing the data, the memory system 110 may resume the maintenance operation. If an error control operation had not been previously performed on data associated with the suspended (and subsequently resumed) maintenance operation, the associated data may be written using a second type of programming operation (e.g., a QLC programming operation, a two-pass programming operation). That is, the memory system 110 may resume the maintenance operation without performing an error control operation on the associated data, which may improve the overall performance of the memory system 110.

The system 100 may include any quantity of non-transitory computer readable media that support concurrent maintenance and write operations. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

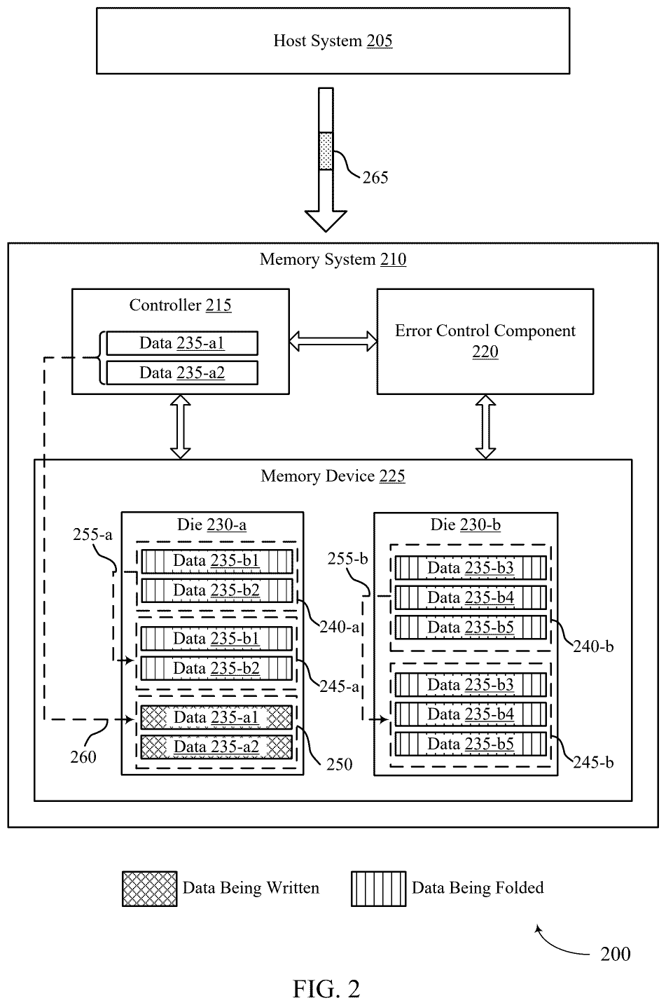

FIG. 2 shows an example of a system 200 that supports concurrent maintenance and write operations in accordance with examples as disclosed herein. The system 200 may be an example of a system 100 as described with reference to FIG. 1, or aspects thereof. For example, the system 200 illustrates a host system 205 and memory system 210 including a memory system controller 215 and an error control component 220, where the host system 205, the memory system 210, and the memory system controller 215 may be examples of a host system 105, memory system 110 and a memory system controller 115, respectively, as described with reference to FIG. 1. The system 200 may illustrate writing data 235 to and transferring (e.g., folding) data 235 between blocks of one or more dies 230, which may be examples of one or more dies 160 as described with reference to FIG. 1.

The memory system controller 215 may perform one or more maintenance operations 255 in which data is folded (e.g., transferred) from blocks 240 to blocks 245 within the die 230 (e.g., or another die 230). In some cases, a folding operation may include transferring data from lower-density (e.g., SLC blocks) to higher-density blocks (e.g., QLC blocks). In other examples, the folding operation may include transferring data from TLC blocks or QLC block to QLC blocks. In some examples, the memory system controller 215 may represent a controller including volatile memory, such as SRAM, among other types of volatile memory. For example, the memory system controller 215 may include a buffer (e.g., including the local memory 120) that includes SRAM memory.

The memory system 210 may include any quantity of dies 230, and each die 230 may each include any quantity of blocks 240, blocks 245, and blocks 250, which may be referred to as data blocks (e.g., blocks of memory cells for storing data). In some examples, the data blocks may be examples of virtual blocks 180 or blocks 170 (e.g., physical blocks 170) as described with reference to FIG. 1. In the example of FIG. 2, the die 230-a may include a block 240-a, a block 245-a, and a block 250. The die 230-b may include a block 240-b and a block 245-b. Each of the block 240, the block 245, and the block 250 may be operable to store respective data 235 in one or more pages (e.g., pages 175) of the respective block.

In some examples, a block 240, a block 245, or a block 250 may represent a source data block or a destination data block depending on how the block is used during one or more access, write, or transfer operations. For example, a source data block 240 may be a data block from which data is transferred as part of a maintenance operation 255, a destination data block 245 may be a data block to which data is transferred as part of a maintenance operation 255, and a block 250 may be a data block to which the memory system controller 215 writes data as part of a programming operation 260 associated with a write command 265 from the host system 205.

In some cases, the block 240, the block 245, and the block 250 may include memory cells that may be operated as SLCs, MLCs, TLCs, or QLCs (e.g., at a given time). That is, in some cases, memory cells of a data block may be programmed as one type of memory cell at a first time and as a second type of memory cell at a second time (e.g., after erasure of the data block). In some other cases, some data blocks may include a fixed (e.g., unchanging) type of memory cell. Relatively lower storage density memory cells, (e.g., memory cells storing fewer bits per memory cell, such as SLCs, MLCs, and TLCs) may be associated with relatively faster program times (e.g., TPROG) compared to higher storage density memory cells, (e.g., QLCs). For example, SLCs and TLCs may have a TPROG of approximately 85 μs and 300 μs, respectively, whereas QLCs may have a TPROG of approximately 3 ms or longer due to QLCs being written using a two-pass programming operation. In some cases, programming data to (e.g., writing to) QLCs may include two-pass programming including performing two operations (e.g., stages, passes) to accurately program one or more QLCs. For example, a first pass of programming a QLC may span a duration of 2 ms (among other possible durations), whereas a second pass of programming a QLC may span a duration of 3 ms (among other possible durations). As part of the two-pass programming operation, data may be retained longer in caches or other volatile memory to support the full operation. Additionally, error control operations (e.g., ECC or EDC) may be performed as part of each stage of the multi-stage programming operation.

In some cases, host write operations associated with the data blocks (e.g., the block 250) may be SLC programming operations. In other examples, host write operations may be TLC or QLC programming operations. For example, if used to store data as part of a host write, a relatively low quantity of bits of data (e.g., one bit, two bits, three bits) may be written to memory cells of the block 250, which may support faster writing to the block 250. In some examples, blocks 240 may include lower storage density memory cells or higher storage density memory cells and be source data blocks for maintenance operations, while the blocks 245 may include relatively high storage density memory cells (e.g., QLCs). In some examples, blocks 240 may include relatively higher storage density memory cells, for example, if previously functioning as a destination data block for maintenance operations.

The memory system controller 215 may perform one or more programming operations 260 in response to one or more write commands 265 received from a host system 205. For example, the memory system controller 215 may receive a write command 265 from the host system 205 to write data 235-a1 and 235-a2 to the memory system 210. The memory system controller 215 may temporarily store the data 235-a1 and 235-a2 within a buffer of the memory system controller 215 (e.g., a local memory 120) before transferring (e.g., writing) the data to the memory device 225. The memory system controller 215 may determine a location within the memory system 210 to which write the data 235-a1 and 235-a2, such as to one or more pages of the block 250.

Additionally, or alternatively, the error control component 220 of the memory system 210 may communicate with the memory system controller 215 to generate and store error control information associated with each of the data 235-a1 and the data 235-a2. In some examples, the error control component 220 may be configured to perform error control operations on data, such as an error correction code (ECC) operation or an error detection operation. For example, the error control component 220 may generate one or more first parity bits associated with each of the data 235-a1 and data 235-a2. After the memory system controller 215 stores the data within the buffer, and after the error control component 220 generates and stores the error control information, the memory system controller 215 may write the data 235-a1 and the data 235-a2 to one or more pages of the block 250. In other instances, the error control component 220 may not generate error control information associated with data received from the host system 205.

The memory system controller 215 may determine to transfer (e.g., fold) data 235 from one or more of the blocks 240 to one or more of the blocks 245 as part of a maintenance operation (e.g., folding data from SLC, TLC, or QLC blocks to QLC blocks). The memory system controller 215 may begin folding data 235 (e.g., initiate a transfer of the data 235) from pages of one or more blocks 240 to one or more blocks 245 (e.g., to free blocks 240 such that the blocks 240 may be erased) as part of a maintenance operation 255. In the example of FIG. 2, the memory system controller 215 may fold the data 235-b1 and 235-b2 from the block 240-a to the block 245-a (e.g., within the same die 230-a). Similarly, the memory system controller 215 may fold the data 235-b3, 235-b4, 235-b5 from the block 240-b to the block 245-b. In some examples, data may be folded from a source data block 240 in one die 230 to a destination data block 245 in a different die 230.

Prior to folding the data 235 from the source data block 240 to the destination block 245, the error control component 220 of the memory system 210 may generate one or more second parity bits associated with the data 235, and may compare the one or more second parity bits to the one or more first parity bits (e.g., by interfacing with the memory system controller 215). In the case that the one or more second parity bits and the one or more first parity bits match (e.g., are the same, include less than a threshold quantity of differences), no errors may be included in the data 235 and the memory system controller 215 may move the data 235 without performing an error control operation. If, however, the one or more second parity bits and the one or more first parity bits do not match, an error may be included in the data 235 and the error control component 220 may correct the erroneous data (or send an indication to the host system 205 indicating such) prior to the memory system 210 writing the data 235 to the destination data block 245-a.

In some examples, the memory system controller 215 may suspend (e.g., or delay) operations when a write command is received from the host system 205. Accordingly, the memory system controller 215 may not reserve (e.g., designate) one or more dies 230 exclusively for host writing, but rather multiple (e.g., all) dies 230 may be used for maintenance operations 255 (e.g., folding operations 255) and host write operations.

For example, the memory system controller 215 may receive (e.g., from a host system 205) a command indicating to write data 235-a1 to a die 230 and may store the data 235-a1 in the buffer of the memory system controller 215. In response to receiving the write command 265, the memory system controller 215 may suspend or delay the maintenance operation 255-a on die 230-a and write the data 235-a1 to the die 235-a while the maintenance operation 255-a is suspended. After the programming operation 260 is completed, the memory system controller 215 may resume the maintenance operation 255-a on the die 230-a. The maintenance operation 255-a and the programming operation 260 may occur concurrently with the maintenance operations of one or more other dies 230 (e.g., folding operation 255-b on die 230-b).

In some examples, each die 230 (or each of the block 240, the block 245, and the block 250 within a die 230) may be associated with a respective latch or set of latches. For example, each die 230 may include a set of latches, and each latch (e.g., of the set of latches) may be able to store a single bit of data. During a maintenance operation, data may be stored (e.g., temporarily) to a latch after being read from a source block and before being written to a destination block. That is, data may be read from a first block (e.g., a source block), stored to one or more latches, and may be transferred from the latch(es) to a second block (e.g., a destination block). Similarly, during a host write operation, data may be stored to one or more latches before being written to a block.

In some instances, when a maintenance operation is suspended in order for a host write operation to be performed, at least a portion of the data associated with the maintenance operation may be stored to one or more latches. Thus, some or all of the data stored to the latches may be overwritten. That is, the programming operation 260 may overwrite one or more latches that contain the data 235 associated with the maintenance operation (e.g., the data 235-b1, the data 235-b2). For example, as part of transferring the data 235-b1 and the data 235-b2 from the source data block 240-a of the die 230-a to the destination data block 245-a, the memory system controller 215 may write (e.g., transfer) the data 235-b1 and the data 235-b2 from the source data block 240-a to the one or more latches of the memory system 210 (e.g., to subsequently write the latched data 235-b to the destination data block 245-a). In some cases, to support performing the programming operation 260, the memory system controller 215 may overwrite the data 235-b1 in the one or more latches with the data 235-a1 (e.g., to support writing the data 235-a1 to the die 230-a from the one or more latches).

After the host write operation is performed, the memory system controller 215 may rewrite the data 235-b1 associated with the maintenance operation to the one or more latches. In examples, when the data 235-b1 was originally written to the block 240-a, error control operations may have been performed and the data 235-b1 may have been stored to the block 240-a with a corresponding set of parity bits (or a single parity bit). In the case that the memory system controller 215 (e.g., the error control component) may have performed an error control operation on the data 235-b1, the memory system controller 215 may also store an indication that an error control operation was performed.

In response to completing the programming operation 260, the memory system controller 215 may read (e.g., access) the stored indication. If the stored indication indicates (e.g., to the memory system controller 215) that an error controller operation was performed on the data 235-b1, the memory system controller 215 may read out the data 235-b1 to the memory system controller 215. The memory system controller 215 may communicate the data 235-b1 with the error control component 220, the error control component 220 may perform an error control operation on the data 235-b1, and may communicate the data 235-b1 back to the memory system controller 215. In response to completing the error control operation, the memory system controller 215 may write the data 235-b1 back to one or more latches. In some examples, the memory system controller 215 may write the data 235-b1 to one or more SLC blocks prior to writing the data 235-b1 to the one or more latches. For example, in response to completing the error control operation, the memory system controller 215 may write the data 235-b1 to one or more SLC blocks, and may write the data 235-b1 to the one or more latches in response to writing the data 235-b1 to the SLC blocks. In some other examples, the memory system controller 215 may write the data 235-b1 directly to the one or more latches (e.g., may not write the data 235-b1 back to the SLC blocks prior to writing the data 235-b1 to the one or more latches). After restoring the data 235-b1 to the latches, the memory system controller 215 may resume the maintenance operations 255. In some examples, the memory system 210 (e.g., the memory system controller 215) may initiate this process each time a maintenance operation is suspended.

In some instances, however, the memory system controller 215 may refrain from performing an error control operation on the data 235-b1 when an error control operation was not previously performed on the data 235-b1. That is, when the data 235-b1 was originally written to the block 240-a, error control operations may not have been performed. Instead, the data 235-b1 may have been stored to the block 240-a without a corresponding set of parity bits (or a single parity bit) being generated. In the case that the memory system controller 215 (e.g., the error control component) may not have performed an error control operation on the data 235-b1, the memory system controller 215 may also store an indication that an error control operation was not performed.

In the case that the data 235-b1 (or a portion of the data 235-b1) is stored to a latch and overwritten by data associated with a host write command, upon resumption of the maintenance operation, the memory system controller 215 may read (e.g., access) the stored indication. If the stored indication indicates to the memory system controller 215 that an error controller operation was not performed on the data 235-b1, the memory system controller 215 may transfer the data 235-b1 (or the portion of the data 235-b1) back to the latch. The memory system controller 215 may then resume the maintenance operation without performing an intervening error control operation, which may improve the overall latency and performance of the memory system 210. That is, by transferring the data 235-b1 directly to the latches upon resuming the maintenance operation, the memory system 210 may improve its overall latency by refraining from sending the data out to the error control component 220 to perform an error control operation. Instead, the data may be transferred directly between latches in a memory device 225, which may use less time than sending data to controllers.

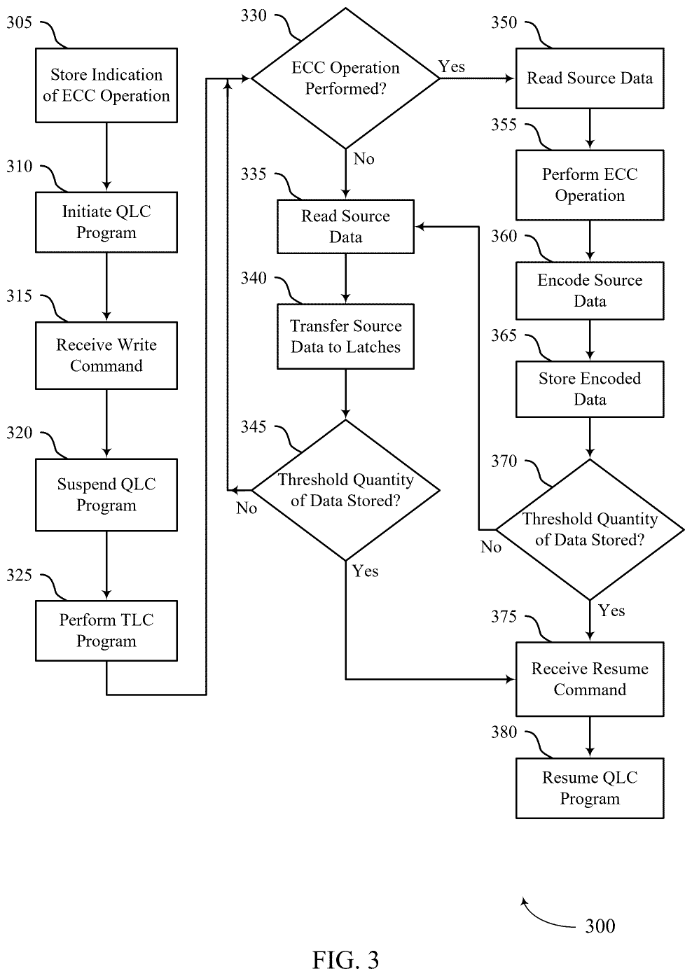

FIG. 3 shows an example of a process 300 that supports concurrent maintenance and write operations in accordance with examples as disclosed herein. The process 300 may be implemented by an example of a system 100 or a system 200 as described with reference to FIGS. 1 and 2, respectively, or by aspects thereof. For example, the process 300 may be implemented by a host system and a memory system that may include a memory system controller, an error control component, and a memory device, which may be examples of a host system 105, a host system 205, a memory system 110, a memory system 210, a memory system controller 115, a memory system controller 215, an error control component 220, and a memory device 225, as described with reference to FIGS. 1 and 2, respectively. The process 300 may illustrate performing a QLC program (e.g., a program operation, a maintenance operation, a folding operation) and a TLC program (e.g., a programming operation), which may be examples of the maintenance and programming operations as described with reference to FIGS. 1 and 2, respectively.

The memory system may perform maintenance operations (e.g., as part of folding operations) on multiple dies of the memory system and may suspend (e.g., or delay) the maintenance operations to perform one or more programming operations using a single-pass programming operation. In some examples, the programming operation may include overwriting one or more latches that store the data associated with the maintenance operation (e.g., first data). After completion of the programming operation, the memory system may rewrite the data associated with the maintenance operation to the one or more latches and may resume performing the maintenance operation using a two-pass programming operation.

In some examples, the process of rewriting the data to the latches may include multiple steps. For example, to rewrite the data to the overwritten latches, the memory system may transfer the data from the memory device to the memory system controller, from the memory system controller to the error control component for error control operations, back to the memory system controller, and then to the overwritten latches for resumption of the maintenance operations. Accordingly, by refraining from performing an error control operation on data not having undergone a previous error control operation, the overall latency of the memory system may be decreased, and its overall performance may be improved.

As described herein, the memory system may be configured to support a higher rate associated with the maintenance operations and, consequently, a higher rate of host writing. For example, the memory system may be performing a maintenance operation (e.g., a folding operation) and a write command may be received (e.g., from a host system). The memory system may suspend the maintenance operation and may write data associated with the write command using a first type of programming operation (e.g., a TLC programming operation, a single-pass programming operation). After writing the data, the memory system may resume the maintenance operation. If an error control operation had not been previously performed on data associated with the suspended (and subsequently resumed) maintenance operation, the associated data may be written using a second type of programming operation (e.g., a QLC programming operation, a two-pass programming operation). That is, the memory system may resume the maintenance operation without performing an error control operation on the associated data, which may simplify the path of the data and improve the overall performance of the memory system.

At 305, an indication of an error control operation may be stored. For example, the memory system may store an indication of whether the error control component performed an error correction operation on first data based on writing the first data to the memory device. In some examples, the indication may be a value indicating either that an error correction operation was performed on the first data or that an error correction operation was not performed on the first data. In some instances, the indication may be accessible by firmware of the memory system.

At 310, a programming operation may be initiated. For example, the memory system may initiate a QLC programming operation (e.g., a maintenance operation) on the first data stored to one or more of the blocks of the memory system. In some examples, the QLC programming operation may be part of a maintenance operation to transfer the first data from one or more SLCs to one or more QLCs. Additionally, or alternatively, in some examples, the SLCs and the QLCs may be located within the same die of the memory system, or may be located in different dies of the memory system. To initiate the QLC programming operation, the memory system may load the first data to one or more latches within the memory system.

At 315, a write command may be received. For example, after initiating the QLC programming operation, the memory system may receive a write command from the host system. The write command may be associated with writing second data to the memory system using a TLC programming operation.

At 320, the programming operation may be suspended. For example, based on receiving the write command, the memory system may suspend (e.g., temporarily suspend, suspend for a duration, pause) the QLC programming operation.

At 325, the programming operation associated with the write command may be performed. For example, in response to suspending the QLC programming operation, the memory system may perform the TLC programming operation. In some examples, performing the TLC programming operation may include writing the second data associated with the write command to one or more of the latches storing the first data associated with the QLC programming operation. That is, to perform the TLC programming operation, the memory system may overwrite at least a portion of the first data stored to the latches with the second data associated with the write command. After performing the TLC programming operation, the memory system may write the second data stored to the overwritten latches to the memory system (e.g., TLCs within the memory system).

At 330, it may be determined whether an error control operation was performed. For example, in response to performing the TLC programming operation (e.g., completing the TLC programming operation operation), the memory system may determine whether an error control operation was performed on the first data by reading the value indicating whether an error control operation was performed on the first data (e.g., the stored indication). In the case that the memory system determines that an error control operation was not performed on the first data (e.g., by accessing the indication, the value), a subsequent error control operation may not be performed on the source data. In the case, however, that the memory system determines that an error control operation was performed on the source data, a subsequent error control operation (e.g., a second error control operation) may be performed on the source data.

At 335, source data may be read. For example, in response to determining that an error control operation has not been performed on the first data, the memory system may read the source data of the first data from the memory system. In some examples, the source data may be data associated with the QLC programming operation that was previously overwritten during the TLC programming operation. In some cases, all of the latched data associated with the QLC programming operation may have been overwritten during the TLC programming operation, and the memory system may read (e.g., re-read) all of the source data. In some other cases, a portion (e.g., a subset) of the data associated with the QLC programming operation may have been overwritten during the TLC programming operation, and the memory system may read a portion (e.g., a subset) of the source data.

At 340, the source data may be transferred to the latches. For example, in response to the memory system reading the source data from the memory system, the memory system may transfer the source data directly to the one or more latches that were overwritten during the TLC programming operation (e.g., without performing an error correction operation, without transferring to the error control component). In some examples, each latch may have a storage ability of 48 kB. In the case that the TLC programming operation overwrote two (e.g., 2) latches with the second data, for example, 96 kB of data may be overwritten. The memory system may transfer a portion of source data corresponding to the portion of data overwritten in the latches. In the example of two latches being overwritten during the TLC programming operation, the memory system may transfer 96 KB of source data to the overwritten latches such that a threshold quantity of first data may be available for the resumption of the QLC programming operation.

At 345, it may be determined whether the threshold quantity of first data has been stored. For example, in response to transferring the source data (e.g., of the first data) to the latches overwritten by the TLC programming operation, the memory system may determine whether the quantity of first data stored to the latches satisfies the threshold quantity of data. In some examples, the QLC programming operation may utilize four (e.g., 4) latches, or 192 kB of data. In the case that two latches (e.g., 96 kB) are overwritten by the TLC programming operation, the memory system may verify that 96 kB of source data were successfully transferred to the latches (e.g., at 340) and that the threshold quantity of first data (e.g., 192 KB) is loaded onto the latches. If the memory system determines that the threshold quantity of data is stored to the latches, a resume command may be received (e.g., at 375). If, however, the memory system determines that the threshold quantity of data is not stored to the latches, the memory system may repeat one or more steps of the process, starting at 330, until the threshold quantity of data is stored to the latches.

At 350, source data may be read. For example, in response to determining that an error control operation was performed on the first data, the memory system may read the source data of the first data from the memory system.

At 355, a second error control operation may be performed. For example, in response to reading the source data from the memory system, the memory system may communicate the source data to the error control component. The error control component may perform one or more second error correction operations on the source data.

At 360, the source data may be encoded. For example, in response to performing the one or more second error correction operations on the source data, the memory system may encode the source data. In some examples, the memory system may communicate the source data from the error control component to the memory system controller, and the memory system controller may encode the source data.

At 365, the encoded source data may be stored. In response to encoding the source data, the memory system may store the encoded source data. In some examples, the memory system controller may communicate the encoded source data to the memory system of the memory system such that the error-corrected, encoded source data may be stored to the one or more latches that were overwritten during the TLC programming operation.

At 370, it may be determined whether the threshold quantity of first data has been stored. For example, in response to storing the encoded source data (e.g., of the first data) to the one or more latches, the memory system may determine whether the quantity of first data stored to the latches satisfies the threshold quantity of data (e.g., as described herein with further detail). If the memory system determines that the threshold quantity of data is stored to the latches, a resume command may be received (e.g., at 375). If, however, the memory system determines that the threshold quantity of data is not stored to the latches, the memory system may repeat one or more steps of the process described herein, starting at 335, until the threshold quantity of data is stored to the latches.

At 375, a resume command may be received. For example, in response to determining that the memory system has stored the threshold quantity of data in the latches, the memory system controller may send a QLC resume command. The memory system may receive the resume command, and may continue on to resuming the suspended QLC programming operation (e.g., at 380).

At 380, the QLC programming operation may be resumed. For example, in response to receiving the resume command, the memory system may resume the suspended QLC programming operation. In some examples, resuming the suspended QLC programming operation may include the memory system performing and completing one or more maintenance operations, folding operations, or both, as described in more detail with reference to FIG. 2.

By resuming the QLC programming operation without performing an error control operation on the associated data (e.g., in the case that a previous error control operation was not performed), the overall latency of the memory system may be decreased, and its performance may be improved. Additionally, refraining from performing a second error control operation may also enable the memory system to support a higher rate of folding and, consequently, a higher rate of host writing such that host write performance constraints may be satisfied (e.g., met, exceeded).

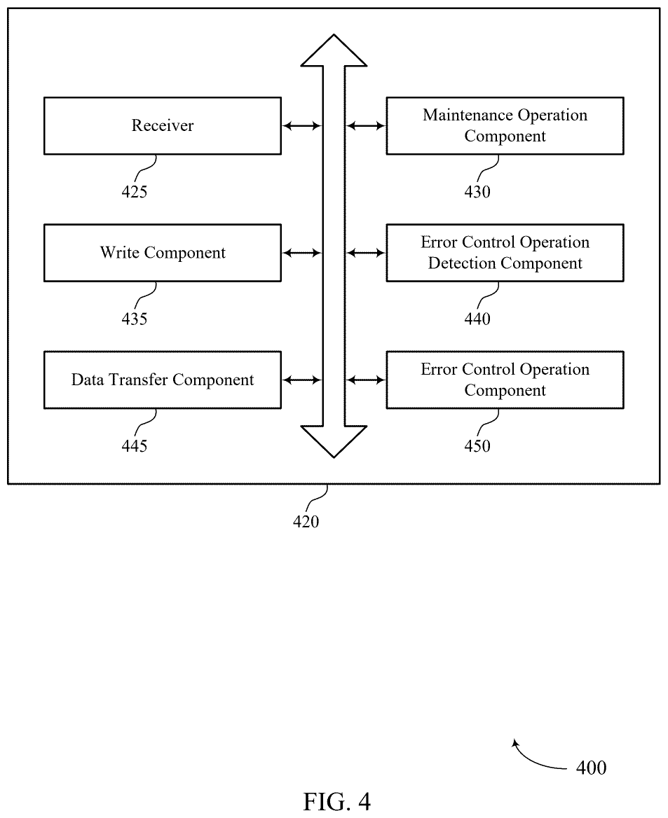

FIG. 4 shows a block diagram 400 of a memory system 420 that supports concurrent maintenance and write operations in accordance with examples as disclosed herein. The memory system 420 may be an example of aspects of a memory system as described with reference to FIGS. 1 through 3. The memory system 420, or various components thereof, may be an example of means for performing various aspects of concurrent maintenance and write operations as described herein. For example, the memory system 420 may include a receiver 425, a maintenance operation component 430, a write component 435, an error control operation detection component 440, a data transfer component 445, an error control operation component 450, or any combination thereof. Each of these components, or components of subcomponents thereof (e.g., one or more processors, one or more memories), may communicate, directly or indirectly, with one another (e.g., via one or more buses).

The receiver 425 may be configured as or otherwise support a means for receiving, at the memory system, a write command to write a first set of data to one or more memory cells of the memory system using a first type of programming operation. The maintenance operation component 430 may be configured as or otherwise support a means for suspending a maintenance operation being performed based at least in part on receiving the write command, where the maintenance operation is associated with a second set of data. The write component 435 may be configured as or otherwise support a means for writing, using the first type of programming operation, the first set of data to the one or more memory cells of the memory system based at least in part on suspending the maintenance operation. The error control operation detection component 440 may be configured as or otherwise support a means for determining whether a first error control operation has been performed on a subset of the second set of data based at least in part on writing the first set of data to the one or more memory cells using the first type of programming operation. The data transfer component 445 may be configured as or otherwise support a means for transferring the subset of the second set of data to a first set of latches for writing to one or more memory cells using a second type of programming operation based at least in part on determining that the first error control operation has not been performed on the subset of the second set of data.

In some examples, the error control operation component 450 may be configured as or otherwise support a means for performing a second error control operation on the subset of the second set of data based at least in part on determining that the first error control operation was performed on the subset of the second set of data.

In some examples, to support performing the second error control operation on the subset of the second set of data, the data transfer component 445 may be configured as or otherwise support a means for transferring, from one or more single-level memory cells of the memory system, the subset of the second set of data. In some examples, to support performing the second error control operation on the subset of the second set of data, the error control operation component 450 may be configured as or otherwise support a means for performing the second error control operation on the subset of the second set of data based at least in part on transferring the subset of the second set of data from the one or more single-level memory cells. In some examples, to support performing the second error control operation on the subset of the second set of data, the data transfer component 445 may be configured as or otherwise support a means for transferring, to one or more quad-level memory cells, the subset of the second set of data based at least in part on performing the second error control operation, where transferring the subset of the second set of data to the first set of latches for writing to the one or more memory cells using the second type of programming operation is based at least in part on transferring the subset of the second set of data to the one or more quad-level memory cells.

In some examples, the subset of the second set of data is stored to the first set of latches during the maintenance operation.

In some examples, to support writing the first set of data to the one or more memory cells of the memory system using the first type of programming operation, the write component 435 may be configured as or otherwise support a means for overwriting the subset of the second set of data stored to the first set of latches during the maintenance operation with the first set of data.

In some examples, the data transfer component 445 may be configured as or otherwise support a means for transferring the first set of data from the first set of latches to the one or more memory cells.

In some examples, the subset of the second set of data is transferred to the first set of latches for writing to the one or more memory cells using the second type of programming operation without a second error control operation being performed on the subset of the second set of data.

In some examples, the maintenance operation includes folding the second set of data from one or more single-level memory cells of the memory system to one or more quad-level memory cells.

In some examples, the maintenance operation component 430 may be configured as or otherwise support a means for resuming the maintenance operation based at least in part on transferring the subset of the second set of data to the first set of latches.

In some examples, the one or more memory cells associated with the first type of programming operation and the one or more memory cells associated with the second type of programming operation are each associated with a same die of the memory system.

In some examples, the maintenance operation component 430 may be configured as or otherwise support a means for initiating, by the memory system, the maintenance operation before receiving the write command to write the first set of data to the one or more memory cells using the first type of programming operation.

In some examples, a second subset of the second set of data is stored to a second set of latches, and the write component 435 may be configured as or otherwise support a means for writing, during a first portion of the second type of programming operation, the second set of data from the first set of latches and the second set of latches to one or more quad-level memory cells based at least in part on transferring the subset of the second set of data to the first set of latches. In some examples, a second subset of the second set of data is stored to a second set of latches, and the write component 435 may be configured as or otherwise support a means for writing, during a second portion of the second type of programming operation, the second set of data from the first set of latches and the second set of latches to the one or more quad-level memory cells based at least in part on writing the second set of data from the first set of latches and the second set of latches to the one or more quad-level memory cells during the first portion of the first type of programming operation.

In some examples, the memory system is performing the maintenance operation when the write command is received.

In some examples, the first type of programming operation includes a single-pass programming operation and the second type of programming operation includes a two-pass programming operation.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

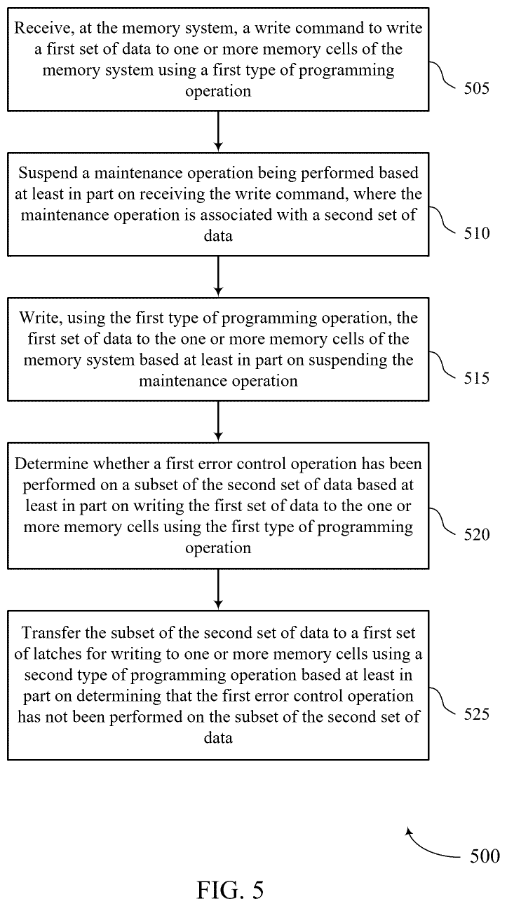

FIG. 5 shows a flowchart illustrating a method 500 that supports concurrent maintenance and write operations in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include receiving, at the memory system, a write command to write a first set of data to one or more memory cells of the memory system using a first type of programming operation. In some examples, aspects of the operations of 505 may be performed by a receiver 425 as described with reference to FIG. 4.

At 510, the method may include suspending a maintenance operation being performed based at least in part on receiving the write command, where the maintenance operation is associated with a second set of data. In some examples, aspects of the operations of 510 may be performed by a maintenance operation component 430 as described with reference to FIG. 4.

At 515, the method may include writing, using the first type of programming operation, the first set of data to the one or more memory cells of the memory system based at least in part on suspending the maintenance operation. In some examples, aspects of the operations of 515 may be performed by a write component 435 as described with reference to FIG. 4.

At 520, the method may include determining whether a first error control operation has been performed on a subset of the second set of data based at least in part on writing the first set of data to the one or more memory cells using the first type of programming operation. In some examples, aspects of the operations of 520 may be performed by an error control operation detection component 440 as described with reference to FIG. 4.

At 525, the method may include transferring the subset of the second set of data to a first set of latches for writing to one or more memory cells using a second type of programming operation based at least in part on determining that the first error control operation has not been performed on the subset of the second set of data. In some examples, aspects of the operations of 525 may be performed by a data transfer component 445 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving, at the memory system, a write command to write a first set of data to one or more memory cells of the memory system using a first type of programming operation; suspending a maintenance operation being performed based at least in part on receiving the write command, where the maintenance operation is associated with a second set of data; writing, using the first type of programming operation, the first set of data to the one or more memory cells of the memory system based at least in part on suspending the maintenance operation; determining whether a first error control operation has been performed on a subset of the second set of data based at least in part on writing the first set of data to the one or more memory cells using the first type of programming operation; and transferring the subset of the second set of data to a first set of latches for writing to one or more memory cells using a second type of programming operation based at least in part on determining that the first error control operation has not been performed on the subset of the second set of data.

Aspect 2: The method, apparatus, or non-transitory computer-readable medium of aspect 1, further including operations, features, circuitry, logic, means, or instructions, or any combination thereof for performing a second error control operation on the subset of the second set of data based at least in part on determining that the first error control operation was performed on the subset of the second set of data.

Aspect 3: The method, apparatus, or non-transitory computer-readable medium of aspect 2, where performing the second error control operation on the subset of the second set of data includes operations, features, circuitry, logic, means, or instructions, or any combination thereof for transferring, from one or more single-level memory cells of the memory system, the subset of the second set of data; performing the second error control operation on the subset of the second set of data based at least in part on transferring the subset of the second set of data from the one or more single-level memory cells; and transferring, to one or more quad-level memory cells, the subset of the second set of data based at least in part on performing the second error control operation, where transferring the subset of the second set of data to the first set of latches for writing to the one or more memory cells using the second type of programming operation is based at least in part on transferring the subset of the second set of data to the one or more quad-level memory cells.

Aspect 4: The method, apparatus, or non-transitory computer-readable medium of any of aspects 1 through 3, where the subset of the second set of data is stored to the first set of latches during the maintenance operation.

Aspect 5: The method, apparatus, or non-transitory computer-readable medium of aspect 4, where writing the first set of data to the one or more memory cells of the memory system using the first type of programming operation includes operations, features, circuitry, logic, means, or instructions, or any combination thereof for overwriting the subset of the second set of data stored to the first set of latches during the maintenance operation with the first set of data.

Aspect 6: The method, apparatus, or non-transitory computer-readable medium of aspect 5, further including operations, features, circuitry, logic, means, or instructions, or any combination thereof for transferring the first set of data from the first set of latches to the one or more memory cells.

Aspect 7: The method, apparatus, or non-transitory computer-readable medium of any of aspects 1 through 6, where the subset of the second set of data is transferred to the first set of latches for writing to the one or more memory cells using the second type of programming operation without a second error control operation being performed on the subset of the second set of data.

Aspect 8: The method, apparatus, or non-transitory computer-readable medium of any of aspects 1 through 7, where the maintenance operation includes folding the second set of data from one or more single-level memory cells of the memory system to one or more quad-level memory cells.

Aspect 9: The method, apparatus, or non-transitory computer-readable medium of any of aspects 1 through 8, further including operations, features, circuitry, logic, means, or instructions, or any combination thereof for resuming the maintenance operation based at least in part on transferring the subset of the second set of data to the first set of latches.

Aspect 10: The method, apparatus, or non-transitory computer-readable medium of any of aspects 1 through 9, where the one or more memory cells associated with the first type of programming operation and the one or more memory cells associated with the second type of programming operation are each associated with a same die of the memory system.

Aspect 11: The method, apparatus, or non-transitory computer-readable medium of any of aspects 1 through 10, further including operations, features, circuitry, logic, means, or instructions, or any combination thereof for initiating, by the memory system, the maintenance operation before receiving the write command to write the first set of data to the one or more memory cells using the first type of programming operation.

Aspect 12: The method, apparatus, or non-transitory computer-readable medium of any of aspects 1 through 11, where a second subset of the second set of data is stored to a second set of latches and the method, apparatuses, and non-transitory computer-readable medium further includes operations, features, circuitry, logic, means, or instructions, or any combination thereof for writing, during a first portion of the second type of programming operation, the second set of data from the first set of latches and the second set of latches to one or more quad-level memory cells based at least in part on transferring the subset of the second set of data to the first set of latches and writing, during a second portion of the second type of programming operation, the second set of data from the first set of latches and the second set of latches to the one or more quad-level memory cells based at least in part on writing the second set of data from the first set of latches and the second set of latches to the one or more quad-level memory cells during the first portion of the first type of programming operation.

Aspect 13: The method, apparatus, or non-transitory computer-readable medium of any of aspects 1 through 12, where the memory system is performing the maintenance operation when the write command is received.

Aspect 14: The method, apparatus, or non-transitory computer-readable medium of any of aspects 1 through 13, where the first type of programming operation includes a single-pass programming operation and the second type of programming operation includes a two-pass programming operation.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
receive, at the memory system, a write command to write a first set of data to one or more memory cells of the memory system using a first type of programming operation;
suspend a maintenance operation being performed based at least in part on receiving the write command, wherein the maintenance operation is associated with a second set of data;
write, using the first type of programming operation, the first set of data to the one or more memory cells of the memory system based at least in part on suspending the maintenance operation;
determine whether a first error control operation has been performed on a subset of the second set of data based at least in part on writing the first set of data to the one or more memory cells using the first type of programming operation; and
transfer the subset of the second set of data to a first set of latches for writing to one or more memory cells using a second type of programming operation based at least in part on determining that the first error control operation has not been performed on the subset of the second set of data.

2. The memory system of claim 1, wherein the processing circuitry is further configured to cause the memory system to:
perform a second error control operation on the subset of the second set of data based at least in part on determining that the first error control operation was performed on the subset of the second set of data.

3. The memory system of claim 2, wherein performing the second error control operation on the subset of the second set of data comprises the processing circuitry configured to cause the memory system to:
transfer, from one or more single-level memory cells of the memory system, the subset of the second set of data;
perform the second error control operation on the subset of the second set of data based at least in part on transferring the subset of the second set of data from the one or more single-level memory cells; and
transfer, to one or more quad-level memory cells, the subset of the second set of data based at least in part on performing the second error control operation, wherein transferring the subset of the second set of data to the first set of latches for writing to the one or more memory cells using the second type of programming operation is based at least in part on transferring the subset of the second set of data to the one or more quad-level memory cells.

4. The memory system of claim 1, wherein the subset of the second set of data is stored to the first set of latches during the maintenance operation.

5. The memory system of claim 4, wherein writing the first set of data to the one or more memory cells of the memory system using the first type of programming operation comprises the processing circuitry configured to cause the memory system to:
overwrite the subset of the second set of data stored to the first set of latches during the maintenance operation with the first set of data.

6. The memory system of claim 5, wherein the processing circuitry is further configured to cause the memory system to:
transfer the first set of data from the first set of latches to the one or more memory cells.

7. The memory system of claim 1, wherein the subset of the second set of data is transferred to the first set of latches for writing to the one or more memory cells using the second type of programming operation without a second error control operation being performed on the subset of the second set of data.

8. The memory system of claim 1, wherein the maintenance operation comprises folding the second set of data from one or more single-level memory cells of the memory system to one or more quad-level memory cells.

9. The memory system of claim 1, wherein the processing circuitry is further configured to cause the memory system to:
resume the maintenance operation based at least in part on transferring the subset of the second set of data to the first set of latches.

10. The memory system of claim 1, wherein the one or more memory cells associated with the first type of programming operation and the one or more memory cells associated with the second type of programming operation are each associated with a same die of the memory system.

11. The memory system of claim 1, wherein the processing circuitry is further configured to cause the memory system to:
initiate, by the memory system, the maintenance operation before receiving the write command to write the first set of data to the one or more memory cells using the first type of programming operation.

12. The memory system of claim 1, wherein a second subset of the second set of data is stored to a second set of latches, and the processing circuitry is further configured to cause the memory system to:
write, during a first portion of the second type of programming operation, the second set of data from the first set of latches and the second set of latches to one or more quad-level memory cells based at least in part on transferring the subset of the second set of data to the first set of latches; and
write, during a second portion of the second type of programming operation, the second set of data from the first set of latches and the second set of latches to the one or more quad-level memory cells based at least in part on writing the second set of data from the first set of latches and the second set of latches to the one or more quad-level memory cells during the first portion of the first type of programming operation.

13. The memory system of claim 1, wherein the memory system is performing the maintenance operation when the write command is received.

14. The memory system of claim 1, wherein the first type of programming operation comprises a single-pass programming operation and the second type of programming operation comprises a two-pass programming operation.

15. A non-transitory computer-readable medium storing code comprising instructions which, when executed by one or more processors of a memory system, cause the memory system to:
receive, at the memory system, a write command to write a first set of data to one or more memory cells of the memory system using a first type of programming operation;
suspend a maintenance operation being performed based at least in part on receiving the write command, wherein the maintenance operation is associated with a second set of data;
write, using the first type of programming operation, the first set of data to the one or more memory cells of the memory system based at least in part on suspending the maintenance operation;
determine whether a first error control operation has been performed on a subset of the second set of data based at least in part on writing the first set of data to the one or more memory cells using the first type of programming operation; and
transfer the subset of the second set of data to a first set of latches for writing to one or more memory cells using a second type of programming operation based at least in part on determining that the first error control operation has not been performed on the subset of the second set of data.

16. The non-transitory computer-readable medium of claim 15, wherein the instructions, when executed by the one or more processors of the memory system, further cause the memory system to:
perform a second error control operation on the subset of the second set of data based at least in part on determining that the first error control operation was performed on the subset of the second set of data.

17. The non-transitory computer-readable medium of claim 16, wherein the instructions to perform the second error control operation on the subset of the second set of data, when executed by the one or more processors of the memory system, further cause the memory system to:
transfer, from one or more single-level memory cells of the memory system, the subset of the second set of data;
perform the second error control operation on the subset of the second set of data based at least in part on transferring the subset of the second set of data from the one or more single-level memory cells; and
transfer, to one or more quad-level memory cells, the subset of the second set of data based at least in part on performing the second error control operation, wherein transferring the subset of the second set of data to the first set of latches for writing to the one or more memory cells using the second type of programming operation is based at least in part on transferring the subset of the second set of data to the one or more quad-level memory cells.

18. The non-transitory computer-readable medium of claim 15, wherein the subset of the second set of data is stored to the first set of latches during the maintenance operation.

19. The non-transitory computer-readable medium of claim 18, wherein the instructions to write the first set of data to the one or more memory cells of the memory system using the first type of programming operation, when executed by the one or more processors of the memory system, further cause the memory system to:
overwrite the subset of the second set of data stored to the first set of latches during the maintenance operation with the first set of data.

20. The non-transitory computer-readable medium of claim 19, wherein the instructions, when executed by the one or more processors of the memory system, further cause the memory system to:
transfer the first set of data from the first set of latches to the one or more memory cells.

21. The non-transitory computer-readable medium of claim 15, wherein the subset of the second set of data is transferred to the first set of latches for writing to the one or more memory cells using the second type of programming operation without a second error control operation being performed on the subset of the second set of data.

22. The non-transitory computer-readable medium of claim 15, wherein the maintenance operation comprises folding the second set of data from one or more single-level memory cells of the memory system to one or more quad-level memory cells.

23. The non-transitory computer-readable medium of claim 15, wherein the instructions, when executed by the one or more processors of the memory system, further cause the memory system to:
resume the maintenance operation based at least in part on transferring the subset of the second set of data to the first set of latches.

24. The non-transitory computer-readable medium of claim 15, wherein the one or more memory cells associated with the first type of programming operation and the one or more memory cells associated with the second type of programming operation are each associated with a same die of the memory system.

25. A method by a memory system, comprising:
receiving, at the memory system, a write command to write a first set of data to one or more memory cells of the memory system using a first type of programming operation;
suspending a maintenance operation being performed based at least in part on receiving the write command, wherein the maintenance operation is associated with a second set of data;
writing, using the first type of programming operation, the first set of data to the one or more memory cells of the memory system based at least in part on suspending the maintenance operation;
determining whether a first error control operation has been performed on a subset of the second set of data based at least in part on writing the first set of data to the one or more memory cells using the first type of programming operation; and
transferring the subset of the second set of data to a first set of latches for writing to one or more memory cells using a second type of programming operation based at least in part on determining that the first error control operation has not been performed on the subset of the second set of data.
